(19) United States
(12) Patent Application Publication
(10) Pub. No.: US 2011/0195186 A1
(43) Pub. Date: Aug. 11, 2011

(54) PLANE-TYPE FILM CONTINUOUS EVAPORATION SOURCE AND THE MANUFACTURING METHOD AND SYSTEM USING THE SAME

(75) Inventors: Chien-Chih Chen, Taichung County (TW); Ching-Chiun Wang, Miaoli County (TW); Ching-Huei Wu, Hsinchu City (TW); Fu-Ching Tung, Hsinchu City (TW)

(73) Assignee: INDUSTRIAL TECHNOLOGY RESEARCH INSTITUTE, Hsinchu (TW)

(21) Appl. No.: 13/024,010

(22) Filed: Feb. 9, 2011

(30) Foreign Application Priority Data
Feb. 9, 2010 (TW) 099103892
Nov. 26, 2010 (TW) 099141055

(51) Int. Cl. C23C 16/44; C23C 16/00

(52) U.S. Cl. 427/248.1; 118/726

(57) ABSTRACT

A manufacturing method and system using a plane-type film continuous evaporation source are disclosed, in which the manufacturing method comprises the steps of: providing a plane-type film continuous evaporation source, being a substrate having at least one evaporation material coated on a surface thereof while distributing the at least one evaporation material in a specific area of the substrate capable of covering all the plates to be processed by the evaporated evaporation material; arranging a heater inside the specific area to be used for enabling the at least one evaporation material to evaporate and thus spreading toward the processed plates. Thereby, the evaporated evaporation material can be controlled at the molecular/atomic level for enabling the same to form a film according to surface-nucleation, condensation and growth with superior evenness, nano-scale adjustability, specialized structure and function that can not be achieve by the films from conventional spray coating means.

### CROSS-REFERENCE TO RELATED APPLICATIONS

This non-provisional application claims benefits and priority under 35 U.S.C. §119(a) on Patent Application No. 099103892 filed in Taiwa, R.O.C. on Feb. 9, 2010 and Patent Application No. 099141055 filed in Taiwa, R.O.C. on Nov. 26, 2010, the entire contents of which are hereby incorporated by reference.

### TECHNICAL FIELD

The present disclosure relates to a plane-type film continuous evaporation source and the manufacturing method and system using the same, and more particularly, to a continuous evaporation technique for large-area thin film deposition capable of achieving precise film quality control with improved high deposition rate and material utilization ratio.

### TECHNICAL BACKGROUND

Evaporation, being a common method for thin film deposition, is a key technique in semiconductor and opto-electronics industries for depositing a thin film on a target object by physical means, especially for the formation of thin films of complex composition, such as copper indium gallium selenide (CIGS) film or organic light-emitting layer for emitting red, green or blue light. Nevertheless, since the evaporation temperature for successfully depositing such thin films of complex composition may varied, and also a satisfactory doping control as well as the concentration of the resulting vapor in the evaporation deposition process are difficult to achieve, not to mention that some material may not be adapted to evaporate in high temperature for deposition as such materials of complex composition may cracked during evaporation or even the components thereof may react chemically with each other, the co-evaporation process for deposition thin films of complex composition is known to be difficult to control.

Since the molecular diffusion rates are different for different evaporated organic materials and they are diffused in all directions, not only a satisfactory doping control is difficult to achieve, but also the material utilization rate is low. Although a precision control relating to the composition of the film to be formed can be achieved by a solution premixing method, it can not be suitably applied in mass production. Taking the process for forming the organic light-emitting layer in an organic light-emitting diode (OLED), since the key factor affecting the uniform illumination of the

OLED is the material composition of its organic light-emitting layer which can be composed of a plurality of dyes, it is clear why the OLED manufacturers had placed most of their R&D resources in such film forming process.

In the conventional film growth technique for OLED devices, it is common to use point evaporation sources. Nevertheless, the adopting of such point evaporation source can only be suitably applied in an evaporation process for forming thin films onto a small-size substrate, such as a piece of 370 mm×470 mm substrate, with a low material utilization rate ranged between 5% to 6%, and a low deposition rate of about 0.3 to 0.8 nm/s in a comparatively longer tact time, i.e. as long as 4 min to 5 min.

There are already studies for solving the aforesaid shortcomings. One of which is a linear evaporation source disclosed in U.S. Pat. No. 6,202,591, entitled “Linear aperture deposition apparatus and coating process”, by which a source material vapor is guided through a rectangular vapor outlet slot of a chimney to direct the source material vapor to a substrate for depositing a single-layer film thereon. It is noted that, by the linear evaporation source of the foregoing patent, a coating with a very high surface thickness uniformity can be achieved under that condition that the deposition rate is increased to about 4 to 5 nm/s, and the material utilization rate is increased to about 80%, and also it can be suitably applied to large-size substrate, such as a piece of 1000 mm×10000 mm substrate, in a comparatively shorter tact time, i.e. its tact time is about 1 min shorter than those conventional processes. However, for single substrate, multiple evaporation processes are still required, and also the foregoing patent had never addressed the aforesaid control problem relating to the co-evaporation process for deposition thin films of complex composition.

Another such study is a white-light organic electroluminescent light-emitting diode and the manufacturing method thereof disclosed in TW Pat. Pub. No. 1293234, in which the manufacturing method comprises the steps of: (a) providing a white-light electroluminescent layer; (b) providing a first electrode at a position abutting against a first surface of the white-light electroluminescent layer; (c) providing a second electrode at a position abutting against a second surface of the white-light electroluminescent layer. It is noted that the white-light electroluminescent layer is manufactured by solution -mixing electroluminescent dyes into molecular host, so that not only the performance of the resulting white-light organic electroluminescent light-emitting diode is improved, but also the manufacturing process thereof is simplified. However, since the aforesaid study only focuses on the mixing of the materials to be evaporated, it is still adapted for conventional batch production that it can not be suitably applied in mass production as there is no continuous production process being provided, and moreover, there is no improvement over the conventional point evaporation source and linear evaporation source.

### TECHNICAL SUMMARY

The present disclosure relating to a plane-type film continuous evaporation source and the manufacturing method and system using the same with the following advantages: (1) the quality of thin film to be formed can be control in a precise manner; (2) a continuous production process for thin film deposition is provided; (3) large-area evaporation is enabled with improved deposition rate and material utilization rate; (4) the material to be evaporated is preventing being subjected under high temperature and thus preventing the same to be degraded thereby.

To achieve the above object, the present disclosure provide a plane-type evaporation method for depositing a film onto a substrate, comprising the steps of: providing at least one evaporation material to be evaporated and a plane-type evaporation source; placing the at least one evaporation material on a surface of the plane-type evaporation source at an area thereof for allowing the at least one evaporation material after being evaporated into a gaseous state to be distributed completely covering a deposition area defined on the substrate for film deposition; heating the plane-type evaporation source so as to transform the solid state evaporation material into its gaseous state while enabling the vapor of the evaporation material to diffuse toward the surface for forming a thin film on the substrate by adopting steam condensation nucleus formation theory.

To achieve the above object, the present disclosure provide a plane-type evaporation source, comprising: a source plate, configured with at least one planer surface; at least one evaporation material to be evaporated, disposed on the at least one planar surface of the source plate on a surface of the plane-type evaporation source at an area thereof for allowing the at least one evaporation material after being evaporated into a gaseous state to be distributed completely covering a deposition area defined on a substrate for film deposition.

Moreover, the present disclosure further provides a method for manufacturing a plane-type evaporation source, comprising the steps of: providing a source plate configured with at least one surface, each selected from the group consisting of: a smooth planar surface, a rough planar surface, a smooth curve surface, a rough curve surface; providing at least one evaporation material to be evaporated while arranging the same to be disposed on the at least one surface of the source plate at an area thereof for allowing the at least one evaporation material after being evaporated into a gaseous state to be distributed completely covering a deposition area defined on a substrate for film deposition; enabling at least one evaporation material to be distributed inside the area of the source plate where the at least one evaporation material is disposed into an array composed of point sources, linear sources or plane-type sources of the at least one evaporation material.

In addition, the present disclosure further provide a plane-type evaporation source system, comprising: at least one substrate, each provided for film deposition; a plane-type evaporation source, configured with at least one source plate and at least one evaporation material in a manner the at least one evaporation material is arranged to be disposed on at least one surface of the source plate at an area thereof for allowing the at least one evaporation material after being evaporated into a gaseous state to be distributed completely covering a deposition area defined on a substrate for film deposition as the substrate is disposed at a position for allowing at least one surface thereof to be reachable by the vapor of the at least one evaporation material; and a heater, disposed at a position corresponding to the area of the source plate where the at least one evaporation material is disposed so as to be used for heating the source plate and thus transform the solid state evaporation material into its gaseous state while enabling the vapor of the evaporation material, either in atom clusters or in molecular clusters, to diffuse toward the substrate for forming a thin film on the surface of the substrate by adopting steam condensation nucleus formation theory.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing the use of a plane-type evaporation source to depositing a thin film on a substrate according to a first embodiment of a plane-type evaporation method in the present disclosure.

FIG. 2 to FIG. 4 are schematic diagrams showing various plane-type evaporation sources of different source plates according to the present disclosure.

FIG. 5 is a schematic diagram showing the use of a plane-type evaporation source to depositing a thin film on a substrate according to a second embodiment of a plane-type evaporation method in the present disclosure.

FIG. 6 to FIG. 8 are schematic diagrams showing the use of various plane-type evaporation sources of different curve source plates in plane-type evaporation method of FIG. 5.

FIG. 9 is a schematic diagram showing a plane-type evaporation source system according to the present disclosure.

FIG. 10 and FIG. 11 are schematic diagrams showing the use of different plane-type evaporation source systems for evaporation depositing films respectively and simultaneously on a plurality of substrates according to the present disclosure.

### DESCRIPTION OF THE EXEMPLARY EMBODIMENTS

For your esteemed members of reviewing committee to further understand and recognize the fulfilled functions and structural characteristics of the disclosure, several exemplary embodiments cooperating with detailed description are presented as the follows.

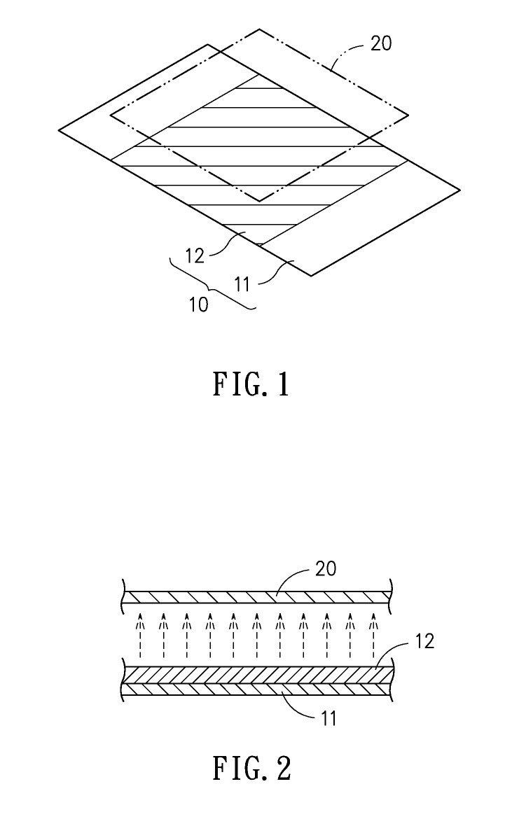

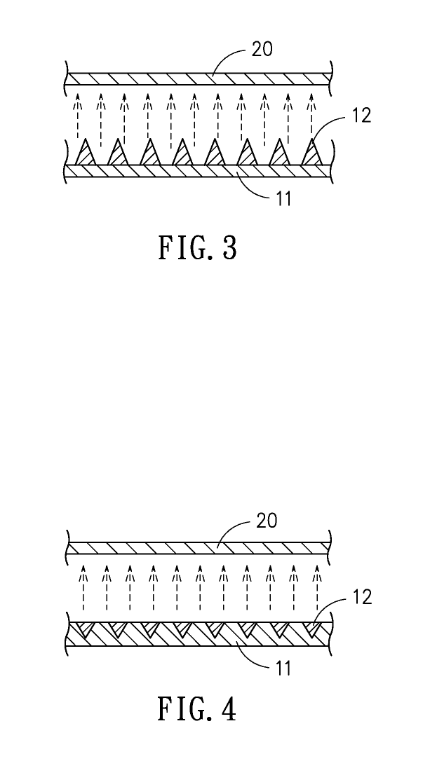

Please refer to FIG. 1, which is a schematic diagram showing the use of a plane-type evaporation source to depositing a thin film on a substrate according to a first embodiment of a plane-type evaporation method in the present disclosure. As shown in FIG. 1, there is a plane-type evaporation source 10 being used for performing a plane-type evaporation process upon a substrate 20, whereas the plane-type evaporation source 10 is configuring with a source plate 11 having at least one surface thereof to be covered by at least one evaporation material, such as the evaporation material 12 shown in FIG. 1, in a manner selected from the group consisting of: coating, ink jetting and evaporation and the like. There can be a variety of source plates 11 that are provided for various evaporation materials 12 to dispose thereon. Please refer to FIG. 2 to FIG. 4, which are schematic diagrams showing various plane-type evaporation sources of different source plates according to the present disclosure. In the embodiment shown in FIG. 2, the source plate 11 is a planar substrate, whereas the evaporation material 12 is formed into a planar film that is covered on a smooth surface of the source plate 11. In the embodiment shown in FIG. 3, the source plate 11 is also a planar substrate, and the evaporation material 12 is not uniformly distributed on a smooth surface of the source plate 11 so as to transform the smooth surface into a rough surface. In the embodiment shown in FIG. 4, the source plate 11 is also a planar substrate, but formed with a rough surface, and the evaporation material 12 is disposed on the rough surface while being filled inside the recesses on the rough surface, in that by changing the densities, the shapes and the sizes of those concaves or protruding dots on the rough surface of the source plate 11, the effective evaporation area of the source plate can be changed and thus the resulting thin film formed on the substrate 20 is adjusted accordingly. Thus, it is noted that each surface of the source plate 11 provided for the evaporation material 12 to dispose thereon can be a surface selected from a smooth planar surface, a rough planar surface, a smooth curve surface and a rough curve surface, and correspondingly, the evaporation material 12 can be formed as a film with a smooth planar surface, a rough planar surface, a smooth curve surface or a rough curve surface that is disposed on the surface of the source plate 11 into an array composed of point sources, linear sources or plane-type sources of the evaporation material, and by a means selected from the group consisting of: coating, ink jetting and evaporation.

The source plate is made of a material with a specific heat resistance. That is, since the source plate is provided for an evaporation process, it is required to be able to withstand a temperature at least higher than 100 and the melting point of the source plate should at least be higher than the working temperature of the evaporation process. Moreover, the evaporation material can be a pure substance or a composition of various substances, such as an evaporation material for forming copper indium gallium selenide (CIGS) films or an organic light-emitting layer for emitting red, green or blue light. Moreover, the evaporation material 12 is coated on a surface of the source plate 11 for forming a layer of evaporation material thereon, and is coated at an area of the source plate 11 for allowing the evaporation material 12 after being evaporated into a gaseous state to be distributed completely covering a deposition area defined on the substrate 20 for film deposition. In FIG. 2, the area of the source plate 12 that is coated by the evaporation material 12 is about the same size as the substrate 20, and thus the whole surface of the source plate 11 is covered by the evaporation material 12, by that the plane-type evaporation source 10 is able to perform a plane-type evaporation process upon the substrate 20, which is obviously different from those conventional point evaporations and linear evaporations.

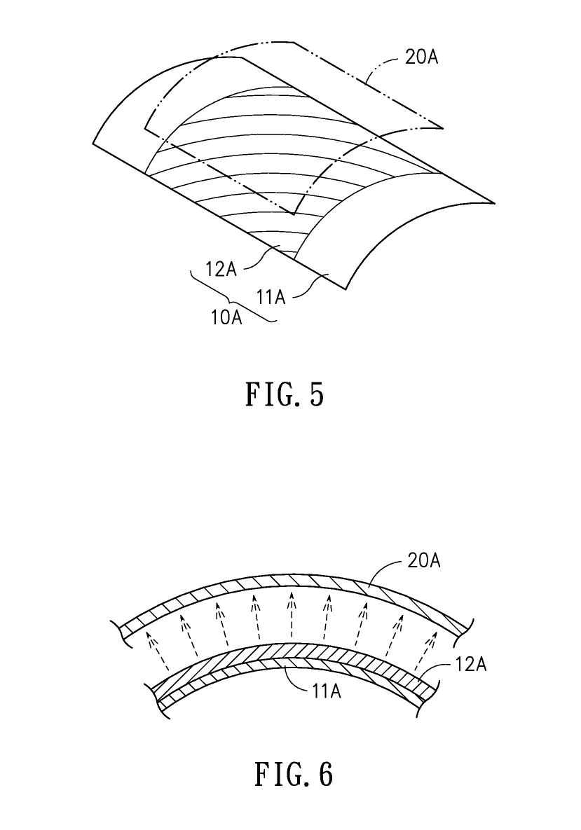

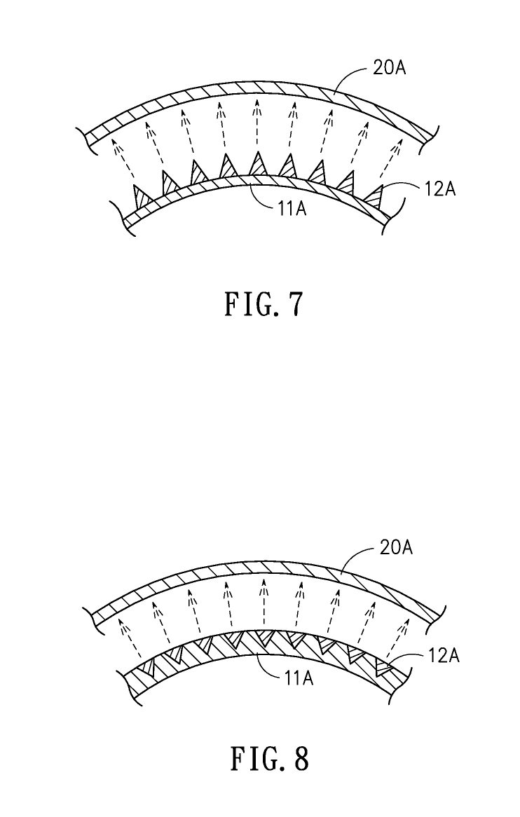

Please refer to FIG. 5, which is a schematic diagram showing the use of a plane-type evaporation source to depositing a thin film on a substrate according to a second embodiment of a plane-type evaporation method in the present disclosure. The embodiment shown in FIG. 5 is basically the same as the one shown in FIG. 1, but is different in that: other than the planar plane-type evaporation source 10 and the planar substrate 20, there is a curved plane-type evaporation source 10A being used for performing a plane-type evaporation process upon a curved substrate 20A. Similarly, the curved plane-type evaporation source 10A is configuring with a curved source plate 11A having at least one surface thereof to be covered by at least one evaporation material, such as the evaporation material 12A shown in FIG. 5, in a manner selected from the group consisting of: coating, ink jetting and evaporation and the like. It is noted that the materials used for making the source plate 11A and the composition of the evaporation material 12A as well as their functions are the same as those disclosed in the first embodiment, but are only featuring in that: the plane-type evaporation source 10A is configured with a curve surface, while enabling the curvature of the curve surface to be adjustable for enabling the same to match with the curvature of the curved substrate 20A. Similarly, there can be a variety of source plates 11A that are provided for various evaporation materials 12A to dispose thereon. Please refer to FIG. 2 to FIG. 4, which are schematic diagrams showing various plane-type evaporation sources of different source plates according to the present disclosure. Please refer to FIG. 6 to FIG. 8, which are schematic diagrams showing the use of various plane-type evaporation sources of different curve source plates in plane-type evaporation method of FIG. 5. In the embodiment shown in FIG. 6, the source plate 11A is a curved substrate, whereas the evaporation material 12A is formed into a curved film that is covered on a smooth surface of the source plate 11A with matching curvature. In the embodiment shown in FIG. 7, the source plate 11A is also a curved substrate, and the evaporation material 12A is not uniformly distributed on a smooth surface of the source plate 11A so as to transform the smooth surface into a rough surface. In the embodiment shown in FIG. 8, the source plate 11A is also a curved substrate, but formed with a rough surface, and the evaporation material 12A is disposed on the rough surface while being filled inside the recesses on the rough surface, in that by changing the densities, the shapes and the sizes of those concaves or protruding dots on the rough surface of the source plate 11A, the effective evaporation area of the source plate can be changed and thus the resulting thin film formed on the substrate 20A is adjusted accordingly.

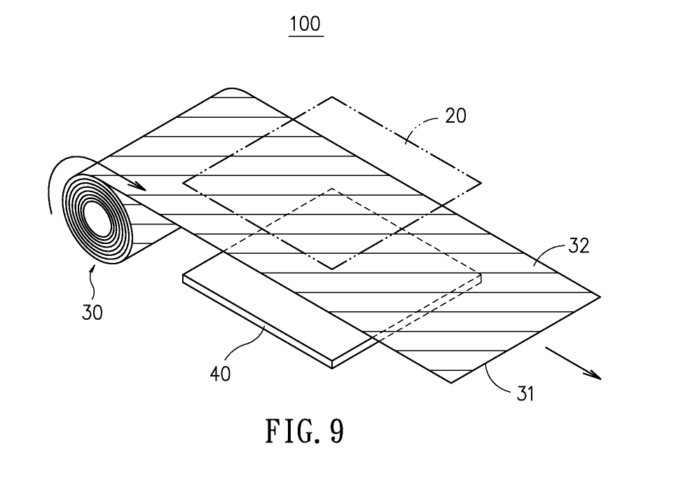

Please refer to FIG. 9, which is a schematic diagram showing a plane-type evaporation source system according to the present disclosure. In FIG. 9, the plane-type evaporation source system 100 includes a plane-type evaporation source 30, which is configured with a source plate 30 and at least one evaporation material 32 in a manner the at least one evaporation material 32 is arranged to be disposed on at least one surface of the source plate 30 in a means selected from the group consisting of: coating, ink jetting and evaporation. Moreover, the area on the source plate 31 that is covered by the at least one evaporation material 32 is the area capable of allowing the at least one evaporation material 32 after being evaporated into a gaseous state to be distributed covering a deposition area defined on a substrate 20 for film deposition, as the shadow area shown in FIG. 9. Similarly, each surface of the source plate 31 provided for the evaporation material 32 to dispose thereon is a surface selected from a smooth planar surface, a rough planar surface, a smooth curve surface and a rough curve surface, as those shown in FIG. 2 to FIG. 8. For instance, it can be formed the same as the source plates 11 and 11A with a center roughness Ra ranged between 0.1 μm to 5 cm. Similarly, the evaporation material 32 can be disposed on the surface of the source plate 31 into an array composed of point sources, linear sources or plane-type sources of the evaporation material, and by a means selected from the group consisting of: coating, ink jetting and evaporation.

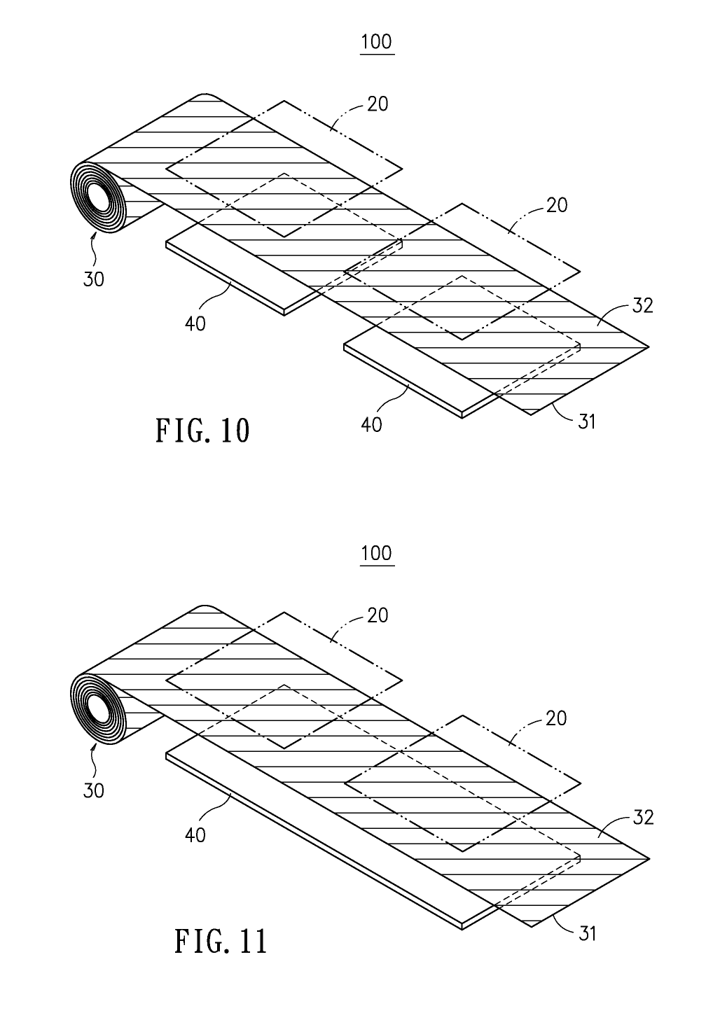

In addition to the evaporation material 32 be coated on a complete surface of the source plate 31, the embodiment is featured in that: the source plate 31 is made of a flexible substrate, and thus the source plate 31, being covered by evaporation material 32, is rolled up into a roll of source plate for enabling the same to be mounted on a feeding device so as to feed the source plate 31 in a manner selected from the group consisting of: a continuous manner and a stepwise manner. As shown in FIG. 9, there are a substrate 20 and a heater 40 being arranged corresponding to two opposite sides of the plane-type evaporation source 30, in that the substrate 20 is positioned facing toward the surface of the source plate 31 which has the evaporation material 32 disposed thereon, and the heater is positioned facing toward the surface of the source plate 31 that is not coated by the evaporation material 32. In the embodiment shown in FIG. 9, as the evaporation material 32 is coated on the top surface of the source plate 31, the substrate is correspondingly being positioned above the plane-type evaporation source 30. In addition, since the substrate 20 should be arranged at a position that can be reached by the vapor of the evaporation material 32, the heater 40 should be disposed at a position corresponding to the area of the source plate 31 where the at least one evaporation material 32 is disposed so as to be used for heating the plane-type evaporation source 30 and thus enable the evaporation material 32 to be transformed into its gaseous state while enabling the vapor of the evaporation material 32, either in atom clusters or in molecular clusters, to diffuse toward the substrate 20 for forming a thin film on a surface of the substrate by adopting a steam condensation and surface nucleation growth mechanism. Moreover, since the plane-type evaporation source 30 is rolled up into a roll that can be sending out in a continuous or stepwise manner, after replacing the substrate 20 that had already been evaporated with a new substrate 20, another evaporation process can be proceeded almost immediately for achieving a continuous evaporation. Please refer to FIG. 10 and FIG. 11, which are schematic diagrams showing the use of different plane-type evaporation source systems for evaporation depositing films respectively and simultaneously on a plurality of substrates according to the present disclosure. In FIG. 10, there can be a plurality of substrates 20 being evaporated in the plane-type evaporation source system at the same time, and correspondingly, there are as many heaters 40 being used. In FIG. 11, there are also a plurality of substrates 20 being evaporated in the plane-type evaporation source system at the same time, but instead of the use of a plurality heaters 40, there is only one huge heater 40 to be used for evaporating the plural substrates 20.

To sum up, in the plane-type film continuous evaporation source and the manufacturing method and system using the same disclosed in the present disclosure, a plane-type evaporation source is formed by coating at least one evaporation material of a mixture of a plurality of evaporation materials on a large-area source plate, whereas the surface of the source plate provided for the evaporation material to dispose thereon can be a surface selected from a smooth planar surface, a rough planar surface, a smooth curve surface and a rough curve surface, as the source plates 11 and 11A shown in FIG. 1 to FIG. 8, and correspondingly, the evaporation material can be formed as a film with a smooth planar surface, a rough planar surface, a smooth curve surface or a rough curve surface that is disposed on the surface of the source plate into an array composed of point sources, linear sources or plane-type sources of the evaporation material, and by a means selected from the group consisting of: coating, ink jetting and evaporation. In addition, the large-area substrate can be a one-piece substrate, and accordingly, there can a series of such one-piece substrates being fed into the plane-type evaporation system continuously for evaporation, as shown in FIG. 1 to FIG. 5. One the other hand, the large-area substrate can be rolled up into a roll of substrate which can be sending out in a manner selected from the group consisting of: a continuous manner and a stepwise manner, and thus to be used in a continuous plane-type evaporation process, as shown in FIG. 9 to FIG. 11. Thereby, a continuous evaporation process for large-area thin film deposition, that is capable of achieving precise film quality control with improved high deposition rate and material utilization ratio, can be achieved and is clearly an improvement over the batch evaporation production performed in the conventional evaporation systems.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A plane-type evaporation method, comprising the steps of:
providing a plane-type evaporation source configuring with a source plate having at least one surface provided to be covered by an evaporation material to be evaporated, while utilizing the plane-type evaporation source to perform a plane-type evaporation process upon a substrate; and
heating the plane-type evaporation source so as to enable the evaporation material to be transformed into its gaseous state while enabling the vapor of the evaporation material to deposit onto a surface of a substrate for forming a thin film thereon.

2. The plane-type evaporation method of claim 1, wherein the evaporation material is disposed on an area of the source plate for allowing the evaporation material after being evaporated into a gaseous state to be distributed completely covering a plurality of substrates for film deposition.

3. The plane-type evaporation method of claim 1, wherein each surface of the source plate provided for the evaporation material to dispose thereon is a surface selected from a smooth planar surface, a rough planar surface, a smooth curve surface and a rough curve surface.

4. The plane-type evaporation method of claim 1, wherein the evaporation material is distributed inside the area of the source plate into an array composed of point sources, linear sources or plane-type sources of the evaporation material.

5. The plane-type evaporation method of claim 1, wherein the source plate is made of a flexible substrate.

6. The plane-type evaporation method of claim 5, wherein the source plate covered by evaporation material is rolled up into a roll of source plate, and the roll of source plate is mounted on a feeding device so as to feed the source plate in a manner selected from the group consisting of: a continuous manner and a stepwise manner, and thus to be used in the plane-type evaporation process.

7. The plane-type evaporation method of claim 1, wherein the evaporation material is composed of at least one substance.

8. A plane-type evaporation source, adapted for performing an evaporation process upon a substrate, comprising:
a source plate, configured with at least one surface; and
at least one evaporation material to be evaporated, disposed on the at least one planar surface of the source plate on the at least one surface of the source plate at an area thereof for allowing the at least one evaporation material after being evaporated into a gaseous state to be distributed completely covering a deposition area defined on a substrate for film deposition.

9. The plane-type evaporation source of claim 8, wherein the evaporation material is disposed on an area of the source plate for allowing the evaporation material after being evaporated into a gaseous state to be distributed completely covering a plurality of substrates for film deposition.

10. The plane-type evaporation source of claim 8, wherein each surface of the source plate provided for the evaporation material to dispose thereon is a surface selected from a smooth planar surface, a rough planar surface, a smooth curve surface and a rough curve surface.

11. The plane-type evaporation source of claim 8, wherein the evaporation material is distributed inside the area of the source plate into an array composed of point sources, linear sources or plane-type sources of the evaporation material.

12. The plane-type evaporation source of claim 8, wherein the source plate is made of a flexible substrate.

13. The plane-type evaporation source of claim 12, wherein the source plate covered by evaporation material is rolled up into a roll of source plate.

14. The plane-type evaporation source of claim 13, wherein the roll of source plate is mounted on a feeding device so as to feed the source plate in a manner selected from the group consisting of: a continuous manner and a stepwise manner, and thus to be used in the plane-type evaporation process.

15. The plane-type evaporation source of claim 8, wherein the evaporation material is composed of at least one substance.

16. A plane-type evaporation system, comprising:
a plane-type evaporation source, configured with a source plate and at least one evaporation material in a manner the at least one evaporation material is arranged to be disposed on at least one surface of the source plate at an area thereof for allowing the at least one evaporation material after being evaporated into a gaseous state to be distributed completely covering a deposition area defined on a substrate for film deposition; and
a heater, disposed at a position corresponding to the area of the source plate where the at least one evaporation material is disposed so as to be used for heating the source plate and thus enable the evaporation material to be transformed into its gaseous state while enabling the vapor of the evaporation material to diffuse toward the substrate for forming a thin film on a surface of the substrate by adopting a steam condensation and surface nucleation growth mechanism.

17. The plane-type evaporation system of claim 16, wherein he evaporation material is disposed on an area of the source plate for allowing the evaporation material after being evaporated into a gaseous state to be distributed completely covering a plurality of substrates for film deposition.

18. The plane-type evaporation system of claim 16, wherein each surface of the source plate provided for the evaporation material to dispose thereon is a surface selected from a smooth planar surface, a rough planar surface, a smooth curve surface and a rough curve surface.

19. The plane-type evaporation system of claim 16, wherein the evaporation material is distributed inside the area of the source plate into an array composed of point sources, linear sources or plane-type sources of the evaporation material.

20. The plane-type evaporation system of claim 16, wherein the source plate is made of a flexible substrate.

21. The plane-type evaporation system of claim 16, wherein the source plate covered by evaporation material is rolled up into a roll of source plate.

22. The plane-type evaporation system of claim 21, wherein the roll of source plate is mounted on a feeding device so as to feed the source plate in a manner selected from the group consisting of: a continuous manner and a stepwise manner, and thus to be used in the plane-type evaporation process.

23. The plane-type evaporation system of claim 16, wherein the evaporation material is composed of at least one substance.
